(19) United States
(12) Patent Application Publication
(10) Pub. No.: US 2026/0197021 A1
(43) Pub. Date: Jul. 9, 2026

(54) RECEIVER CIRCUITS INCLUDING ASYMMETRIC BANDWIDTH COMPENSATION CIRCUIT

(71) Applicant: Samsung Electronics Co., Ltd., Suwon-si (KR)

(72) Inventors: Tongsung Kim, Suwon-si (KR); Woojung Kim, Suwon-si (KR); Hyunwoo Ahn, Suwon-si (KR); Baekjin Lim, Suwon-si (KR)

(21) Appl. No.: 19/417,030

(22) Filed: Dec. 11, 2025

(30) Foreign Application Priority Data
Jan. 8, 2025 (KR) 10-2025-0002883

(51) Int. Cl. H04B 1/16

(52) U.S. Cl. CPC H04B 1/1638; H04B 1/1607

(57) ABSTRACT

Disclosed is a receiver circuit including an asymmetric bandwidth compensation circuit. The receiver circuit includes a differential transistor pair configured to receive an input signal, a pair of output nodes configured to output a response to the input signal, the pair of output nodes including a first output node configured to output a first output signal and a second output node configured to output a second output signal, a third transistor connected between the first output node and the second output node, and a capacitive element connected between an input signal line through which the input signal is received and the third transistor, wherein the second output signal has a response gain superposed on the input signal by the third transistor and the capacitive element.

### CROSS-REFERENCE TO RELATED APPLICATION

This application is based on and claims priority under 35 U.S.C. § 119 to Korean Patent Application No. 10-2025-0002883, filed on Jan. 8, 2025, in the Korean Intellectual Property Office, the disclosure of which is incorporated by reference herein in its entirety.

### BACKGROUND

Efforts for making electronic systems more powerful and power-efficient may develop interface communication, thereby improving throughput while not increasing power consumption, and in an ideal case, while decreasing power consumption. As demands for increasing a system speed, increasing data capacity, and consuming low power increase, semiconductor memories allowing quicker access, storing more data, and using less power than before have been continuously developed.

A semiconductor memory is generally controlled by providing a command, an address, and a clock to a memory device. Various commands, addresses, and clocks may be provided by, for example, a memory controller. A command may control a memory device to perform various memory operations, e.g., a read operation for retrieving data from the memory device and a write operation for storing data in the memory device. The data associated with the command may be provided between the memory controller and the memory device at a timing known with respect to reception and/or transmission by the memory device. Because communication between chips including such a memory controller and/or memory device requires a relatively high speed and a wide bandwidth, it is significant in a chip design to adjust the gain and bandwidth of a receiver circuit.

### SUMMARY

The present disclosure provides receiver circuits including an asymmetric bandwidth compensation circuit to adjust the gain and bandwidth of a receiver circuit.

The present disclosure relates to semiconductor integrated circuits, and more particularly, to receiver circuits including an asymmetric bandwidth compensation circuit.

According to an aspect of the present disclosure, there is provided a receiver circuit including a differential transistor pair configured to receive an input signal, the differential transistor pair including a first transistor configured to receive the input signal and a second transistor configured to receive a reference voltage, a pair of output nodes configured to output a response to the input signal, the pair of output nodes including a first output node connected to a first end of the first transistor and configured to output a first output signal and a second output node connected to a first end of the second transistor and configured to output a second output signal, a third transistor connected between the first output node and the second output node, a control end of the third transistor receiving the first output signal and a first end of the third transistor outputting the second output signal, and a capacitive element connected between an input signal line through which the input signal is received and a second end of the third transistor, wherein the second output signal has a response gain superposed on the input signal by the third transistor and the capacitive element.

According to another aspect of the present disclosure, there is provided a method for a receiver circuit, the method including receiving an input signal and a reference voltage by a differential transistor pair including a first transistor and a second transistor, a first end of a capacitive element being connected to an input signal line through which the input signal is received, and a first end of a third transistor being connected to a second end of the capacitive element, providing currents through a pair of output nodes, the third transistor being connected to a first output node of the pair of output nodes, and outputting a response to the input signal from the pair of output nodes, the first output node of the pair of output nodes outputting a first output signal, a second end of the third transistor being connected to a second output node of the pair of output nodes, and the second output node of the pair of output nodes outputting a second output signal, wherein the second output signal has a response gain superposed on the input signal by the third transistor and the capacitive element.

According to another aspect of the present disclosure, there is provided a receiver circuit including a differential transistor pair configured to receive an input signal and a complementary input signal, the differential transistor pair including a first transistor configured to receive the input signal and a second transistor configured to receive the complementary input signal, a pair of output nodes configured to output a response to the input signal and the complementary input signal, the pair of output nodes including a first output node connected to a first end of the first transistor and configured to output a first output signal and a second output node connected to a first end of the second transistor and configured to output a second output signal, a third transistor connected between the first output node and the second output node, a control end of the third transistor receiving the first output signal and a first end of the third transistor outputting the second output signal, and a capacitive element connected between an input signal line through which the input signal is received and a second end of the third transistor, wherein the second output signal has a response gain superposed on the input signal by the third transistor and the capacitive element.

### BRIEF DESCRIPTION OF THE DRAWINGS

Implementations of the present disclosure will be more clearly understood from the following detailed description taken in conjunction with the accompanying drawings in which:

FIGS. 1, 2, and 3 illustrate a high-speed communication system;

FIGS. 4A, 4B, and 5 illustrate a differential buffer circuit according to implementations;

FIG. 6 is a circuit diagram illustrating a differential buffer circuit according to implementations;

FIG. 7 is a circuit diagram illustrating a differential buffer circuit according to implementations;

FIG. 8 is a circuit diagram illustrating a differential buffer circuit according to implementations;

FIG. 9 is a circuit diagram illustrating a differential buffer circuit according to implementations;

FIG. 10 is a circuit diagram illustrating a differential buffer circuit according to implementations;

FIG. 11 is a cross-sectional view of a memory device having a bonding vertical NAND (B-VNAND) structure including a receiver circuit according to some implementations; and

FIG. 12 is a block diagram of a system for describing an electronic device including a receiver circuit according to implementations.

### DETAILED DESCRIPTION

Receiver(s) described in the present disclosure may receive a high-speed serial data stream, e.g., a serial data stream operating at a level of gigabits per second (Gbps). A receiver circuit may have a differential buffer configured to determine logic high and logic low by comparing a signal input from the outside with a certain reference voltage, and perform an operation of generating a differential pair of output signals through a comparison operation and transmitting the same to internal logic(s). The differential pair of output signals of the receiver circuit may have different output characteristics, and the high-speed data transmission rate of the receiver circuit is determined based on an output signal having a bad characteristic between the differential pair of output signals. Hereinafter, to generate a differential pair of output signals having the same characteristic, a receiver circuit configured to compensate for a direct current (DC) gain and a frequency-dependent loss is provided.

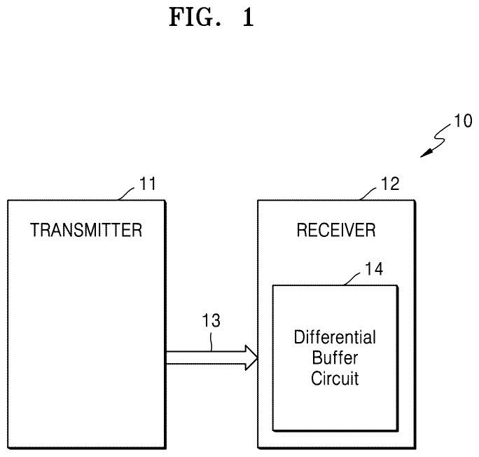

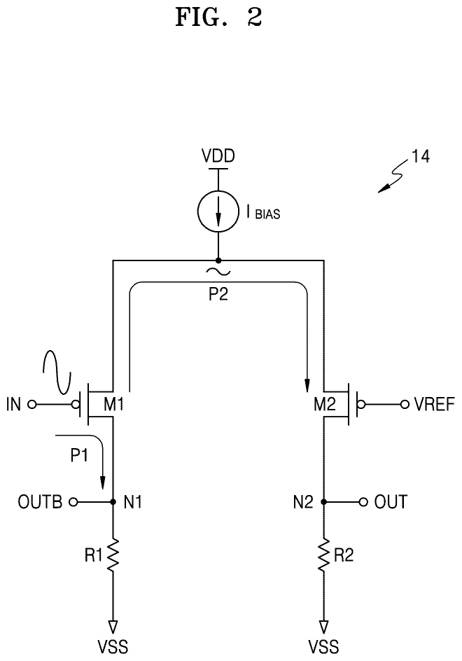

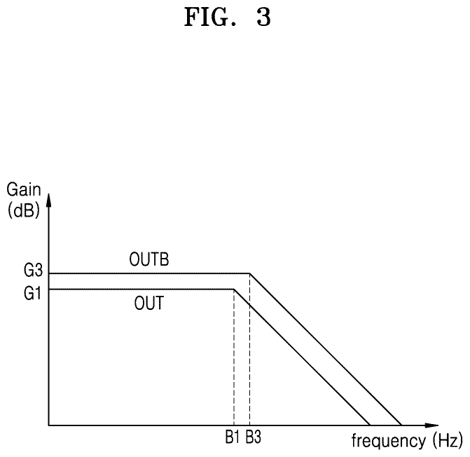

FIGS. 1, 2, and 3 illustrate a high-speed communication system 10. FIG. 1 is a simple block diagram of the high-speed communication system 10, FIG. 2 is a circuit diagram illustrating a differential buffer circuit 14 included in a receiver 12 of FIG. 1, and FIG. 3 is a graph illustrating the gain-to-frequency characteristic of the differential buffer circuit 14 of FIG. 2. The differential buffer circuit 14 corresponds to a component included in the receiver 12 and thus may be referred to as a receiver circuit.

Referring to FIG. 1, the high-speed communication system 10 may include a transmitter 11, the receiver 12, and a channel 13 for data communication between the transmitter 11 and the receiver 12. The high-speed communication system 10 may indicate an integrated circuit, an electronic device or system, a smartphone, a tablet personal computer (PC), a computer, a server, a workstation, a portable communication terminal, a personal digital assistant (PDA), a portable multimedia player (PMP), a computing device, such as other proper computers, a virtual machine or a virtual computing device thereof, or the like. Alternatively, the high-speed communication system 10 may be some of components included in a computing system, such as a graphics card. In the present implementations, although two conceptual hardware components included in the high-speed communication system 10 are shown, the high-speed communication system 10 is not limited thereto and may include other components.

The transmitter 11 may communicate with the receiver 12 through the channel 13. The channel 13 may include a plurality of signal lines physically or electrically connecting the transmitter 11 to the receiver 12. The transmitter 11, the receiver 12, and the channel 13 may support binary signaling for transmitting two states, i.e., a state indicating binary 0 and a state indicating binary 1. The receiver 12 may include the differential buffer circuit 14 configured to receive a serial data stream as an input signal through the channel 13.

Referring to FIG. 2, the differential buffer circuit 14 may compare an input signal IN received by the receiver 12 with a reference voltage VREF and output a first output signal OUTB and a second output signal OUT. The differential buffer circuit 14 has a pseudo differential structure, and the first output signal OUTB is complementary to the second output signal OUT.

The differential buffer circuit 14 may include a current source I_{BIAS}, a first transistor M1, a second transistor M2, a first resistor R1, and a second resistor R2. The current source I_{BIAS} may be connected to a power source voltage VDD and provide a bias current for driving the differential buffer circuit 14. A first end of the current source I_{BIAS} may be connected to a power source voltage VDD line, and a second end of the current source I_{BIAS} may be connected to first ends (sometimes, referred to as the sources) of the first transistor M1 and the second transistor M2.

The first end of the first transistor M1 may be connected to the second end of the current source I_{BIAS}, a second end (sometimes, referred to as the drain) of the first transistor M1 may be connected to a first output node N1, and a control end of the first transistor M1 may receive the input signal IN. The first end of the second transistor M2 may be connected to the second end of the current source I_{BIAS}, a second end (sometimes, referred to as the drain) of the second transistor M2 may be connected to a second output node N2, and a control end of the second transistor M2 may be connected to a reference voltage VREF line. Each of the first transistor M1 and the second transistor M2 may include a P-channel metal-oxide-semiconductor (PMOS) transistor. The first output node N1 and the second output node N2 to which the drains of the first transistor M1 and the second transistor M2 are respectively connected are output ends of the differential buffer circuit 14.

The first resistor R1 may be connected between the first output node N1 and a ground voltage VSS line, and the second resistor R2 may be connected between the second output node N2 and the ground voltage VSS line. The first output node N1 may output the first output signal OUTB of the differential buffer circuit 14, and the second output node N2 may output the second output signal OUT of the differential buffer circuit 14.

The differential buffer circuit 14 may compare the level of the input signal IN with the level of the reference voltage VREF and output, as the first output signal OUTB and the second output signal OUT, the logic levels of the input signal IN determined based on the comparison result. In some implementations, if the level of the input signal IN is higher than the level of the reference voltage VREF, the first output signal OUTB may be output as a logic high level, and the second output signal OUT may be output as a logic low level. Otherwise, if the level of the input signal IN is lower than the level of the reference voltage VREF, the first output signal OUTB may be output as the logic low level, and the second output signal OUT may be output as the logic high level. The accuracy and speed of the differential buffer circuit 14 configured to perform such an operation may be determined based on a gain and a bandwidth according to the frequency of the input signal IN.

Referring to FIG. 3, the gain and bandwidth of the first output signal OUTB of the differential buffer circuit 14 differ from the gain and bandwidth of the second output signal OUT of the differential buffer circuit 14. A gain G3 of the first output signal OUTB is higher than a gain G1 of the second output signal OUT. In addition, a frequency B3 at which the gain G3 of the first output signal OUTB is linear is also higher than a frequency B1 at which the gain G1 of the second output signal OUT is linear. The highest frequency having a linear gain may be referred to as a bandwidth, and the bandwidth B3 of the first output signal OUTB is higher than the bandwidth B1 of the second output signal OUT.

The first output signal OUTB and the second output signal OUT may be output in response to the input signal IN received at a high frequency. The first output signal OUTB and the second output signal OUT are affected by the input signal IN. The first output signal OUTB is output through a first path P1 passing through the first transistor M1 to which the input signal IN is input. The second output signal OUT is output through a second path P2 passing through the first transistor M1, the second end of the current source I_{BIAS}, and a second transistor M2 to which the reference voltage VREF is input. The second path P2 has a higher path loss than the first path P1 due to line loads, and thus, the gain G1 and bandwidth B1 of the second output signal OUT is lower and narrower than the gain G3 and bandwidth B3 of the first output signal OUTB, respectively. The performance of the differential buffer circuit 14 is determined based on the second output signal OUT having the lower gain G1 and narrower bandwidth B1. The performance of the high-speed communication system 10 including the differential buffer circuit 14 may decrease due to the second output signal OUT having the lower gain G1 and narrower bandwidth B1.

The differential buffer circuit 14 may increase the bias current of the current source I_{BIAS}, which drives the differential buffer circuit 14, to increase the gain G1 and the bandwidth B1 of the second output signal OUT. Accordingly, the gains and bandwidths of both the first output signal OUTB and the second output signal OUT may increase. As a result, because the performance of the differential buffer circuit 14 is determined based on the second output signal OUT having a lower gain and a narrower bandwidth, the differential buffer circuit 14 is still unstable. Hereinafter, differential buffer circuits configured to increase the gain G1 and bandwidth B1 of the second output signal OUT by considering the influence of the input signal IN are described.

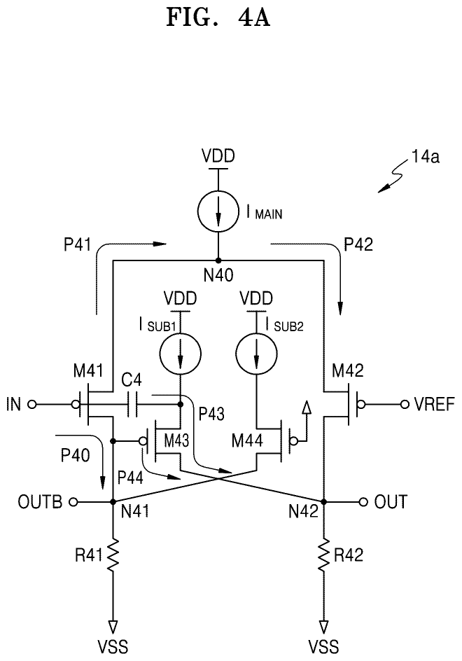

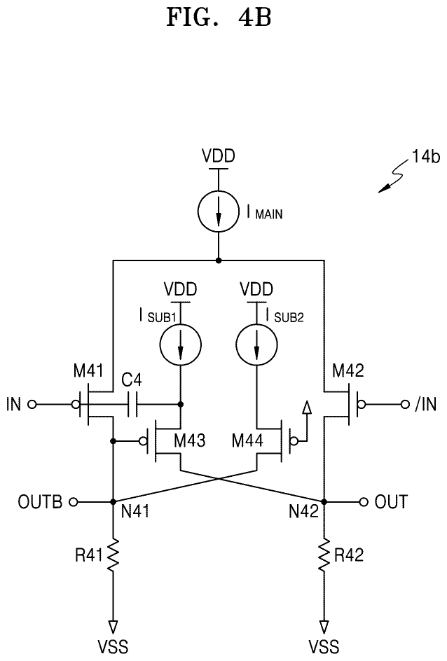

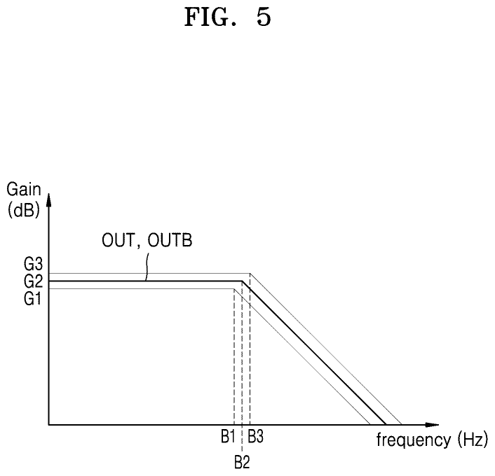

FIGS. 4A, 4B, and 5 illustrate a differential buffer circuit according to some implementations. FIGS. 4A and 4B are circuit diagrams illustrating a differential buffer circuit 14a and 14b included in the receiver 12 of FIG. 1, and FIG. 5 is a graph illustrating the gain-to-frequency characteristic of the differential buffer circuit 14a of FIG. 4A. Hereinafter, subscripts (e.g., a of 14a and b of 14b) attached to the same reference numeral in different drawings are to distinguish a plurality of components having similar or same functions.

Referring to FIG. 4A, the differential buffer circuit 14a may include a first current source I_{MAIN}, a second current source I_{SUB1}, a third current source I_{SUB2}, a capacitor C4, a first transistor M41, a second transistor M42, a third transistor M43, a fourth transistor M44, a first resistor R41, and a second resistor R42. The first current source I_{MAIN}, the second current source I_{SUB1}, and the third current source I_{SUB2} may be connected to the power source voltage VDD and provide a bias current for driving the differential buffer circuit 14a. A first end of the first current source I_{MAIN} may be connected to the power source voltage VDD line, and a second end of the first current source I_{MAIN} may be connected to first ends of the first transistor M41 and the second transistor M42. A first end of the second current source I_{SUB1} may be connected to the power source voltage VDD line, and a second end of the second current source I_{SUB1} may be connected to a first end of the third transistor M43. A first end of the third current source I_{SUB2} may be connected to the power source voltage VDD line, and a second end of the third current source I_{SUB2} may be connected to a first end of the fourth transistor M44.

A first end of the capacitor C4 may receive the input signal IN, and a second end of the capacitor C4 may be connected to the second end of the second current source I_{SUB1} and the first end of the third transistor M43. The first end of the first transistor M41 may be connected to the second end of the first current source I_{MAIN}, a second end of the first transistor M41 may be connected to a first output node N41, and a control end of the first transistor M41 may receive the input signal IN. The first end of the second transistor M42 may be connected to the second end of the first current source I_{MAIN}, a second end of the second transistor M42 may be connected to a second output node N42, and a control end of the second transistor M42 may be connected to the reference voltage VREF line. The first end of the third transistor M43 may be connected to the second end of the second current source I_{SUB1} and the second end of the capacitor C4, a second end of the third transistor M43 may be connected to the second output node N42, and a control end of the third transistor M43 may be connected to the first output node N41. The first end of the fourth transistor M44 may be connected to the second end of the third current source I_{SUB2}, a second end of the fourth transistor M44 may be connected to the first output node N41, and a control end of the fourth transistor M44 may be connected to the ground voltage VSS line. The first to fourth transistors M41, M42, M43, and M44 may include PMOS transistors. According to some implementations, the first to fourth transistors M41, M42, M43, and M44 may include N-channel metal oxide semiconductor (NMOS) transistors.

The first resistor R41 may be connected between the first output node N41 and the ground voltage VSS line, and the second resistor R42 may be connected between the second output node N42 and the ground voltage VSS line. The differential buffer circuit 14a may include a pair of output signal nodes, i.e., the first and second output nodes N41 and N42, for outputting a response to the input signal IN, wherein the first output node N41 outputs a first output signal OUTB of the differential buffer circuit 14a, and the second output node N42 outputs a second output signal OUT of the differential buffer circuit 14a. The first output signal OUTB and the second output signal OUT may have the gains (sometimes, represented by decibel or dB) of frequency-to-responses and frequency poles indicating a frequency at which a gain starts to decrease. A response of the differential buffer circuit 14a may be described as follows.

The differential buffer circuit 14a may output the first output signal OUTB by performing an operation of amplifying the input signal IN through a path P40 from an input signal IN line to the first output node N41. The path P40 may include the first transistor M41, and the first transistor M41 may operate as a first common-source amplifier. A voltage gain Av0 of the first common-source amplifier may be represented by Equation 1.

$$A v 0 = - gm 1 * ( Rd ‖ ro 1 ) \qquad [ Equation 1 ]$$

Herein, gm1 denotes the transconductance of the first transistor M41, Rd denotes the drain resistance of the first transistor M41, and ro1 denotes the output resistance of the first transistor M41. The transconductance may be characterized by the current gains of a differential pair of transistors, i.e., the first and second transistors M41 and M42 of the differential buffer circuit 14a. In addition, Rd indicates the resistance of the first resistor R41 connected to the drain of the first transistor M41.

The first common-source amplifier may generate a first frequency pole f1 at which the voltage gain Av0 starts to decrease. The first frequency pole f1 at which the response gain of the first output signal OUTB starts to decrease may be represented by Equation 2.

$$f1 = ( ro 1 ‖ ro 4 ‖ Rd ) * {C}_{O U T B} \qquad [ Equation 2 ]$$

Herein, ro4 denotes the output resistance of the fourth transistor M44 connected to the first output node N41, and C_{OUTB} denotes the capacitance of a capacitive element and/or at least one capacitive load of the first output node N41.

The differential buffer circuit 14a may output the second output signal OUT by performing an operation of amplifying the input signal IN through paths P41, P42, P43, and P44 from the input signal IN line to the second output node N42.

The path P41 may operate as a source follower amplifier including the first transistor M41. A voltage gain Av1 of the source follower amplifier may be represented by Equation 3.

$$Av 1 = \{ ( \frac{1}{g m 1} ) ‖ ( \frac{1}{g m 2} ) \} / \{ 1 / ( \frac{1}{g m 1} ) + ( \frac{1}{g m 1} ) ‖ ( \frac{1}{g m 2} ) \} < 1 \qquad [ Equation 3 ]$$

Herein, gm2 denotes the transconductance of the second transistor M42. The voltage gain Av1 of the source follower amplifier may be lower than 0 dB that is a unity gain.

The path P42 may operate as a first common-gate amplifier including the second transistor M42. A voltage gain Av2 of the first common-gate amplifier may be represented by Equation 4.

$$Av 2 = gm 2 * ( Rd ‖ ro 2 ‖ ro 3 ) \qquad [ Equation 4 ]$$

Herein, ro3 denotes the output resistance of the third transistor M43 connected to the second output node N42.

The path P43 may operate as a second common-gate amplifier including the third transistor M43. A voltage gain Av3 of the second common-gate amplifier may be represented by Equation 5.

$$Av 3 - gm 3 * ( Rd ‖ ro 2 ‖ ro 3 ) \qquad [ Equation 5 ]$$

Herein, gm3 denotes the transconductance of the third transistor M43.

The path P44 may operate as a second common-source amplifier including the third transistor M43. A voltage gain Av4 of the second common-source amplifier may be represented by Equation 6.

$$Av 4 = Av 0 * gm 3 * ( Rd ‖ ro 2 ‖ ro 3 ) \qquad [ Equation 6 ]$$

A total gain Avt of the second output signal OUT responding to the input signal IN through the paths P41, P42, P43, and P44 connected to the second output node N42 may be represented by Equation 7.

$$Avt = Av 1 * Av 2 + ( Av 3 + Av 4 ) \qquad [ Equation 7 ]$$

The paths P41, P42, P43, and P44 of the differential buffer circuit 14a have a second frequency pole f2 and a third frequency pole f3 at which the total gain Avt of the second output signal OUT responding to the input signal IN starts to decrease. The second frequency pole f2 may be represented by Equation 8, and the third frequency pole f3 may be represented by Equation 9.

$$f 2 = ( \frac{1}{gm 1} ) ‖ ( \frac{1}{gm 2} ) * {C}_{N 40} \qquad [ Equation 8 ]$$

Herein, C_{N40} denotes the capacitance of a capacitive element and/or at least one capacitive load of a second end node N40 of the first current source I_{MAIN} to which the first transistor M41 and the second transistor M42 are connected.

$$f 3 = ( ro 1 ‖ ro 4 ‖ Rd ) * {C}_{OUT} \qquad [ Equation 9 ]$$

Herein, C_{OUT} denotes the capacitance of a capacitive element and/or at least one capacitive load of a second output signal OUT line.

The differential buffer circuit 14a has a frequency response difference between the first output signal OUTB and the second output signal OUT that are responses to the input signal IN. The first output signal OUTB has one frequency pole, i.e., the first frequency pole f1, whereas the second output signal OUT has two frequency poles, i.e., the second and third frequency poles f2 and f3. This means that the gain G1 of the second output signal OUT is less than the gain G3 of the first output signal OUTB, as shown in FIG. 2. In addition, a bandwidth is narrow as a gain is low, and thus, the bandwidth B1 of the second output signal OUT is narrower than the bandwidth B3 of the first output signal OUTB.

To increase the gain and bandwidth of the second output signal OUT, the differential buffer circuit 14a may make alternating current (AC) coupling of the input signal IN affect the second output signal OUT through the capacitor C4 of the path P43. In addition, the differential buffer circuit 14a relatively simply provides a bias circuit by inputting the first output signal OUTB to the control end of the third transistor M43 and provides the gain Av4 of the fourth transistor M44 as a function of the transconductance gm3 of the third transistor M43 (Equation 6). Accordingly, the differential buffer circuit 14a may provide superposition to the second output signal OUT by amplifying the first output signal OUTB. In this scheme, the third transistor M43 and the capacitor C4 function as an asymmetric bandwidth compensation circuit configured to compensate for the gain and bandwidth of a second output signal path having a low gain and a narrow bandwidth. The differential buffer circuit 14a may increase the gain and bandwidth of the second output signal OUT and has a gain-to-frequency characteristic, as shown in FIG. 5.

Referring to FIG. 5, the first output signal OUTB and the second output signal OUT of the differential buffer circuit 14a are stabilized at a gain G2 and a bandwidth B2. The differential buffer circuit 14a outputs the first output signal OUTB down-converted from the gain G3 into the gain G2 and from the bandwidth B3 into the bandwidth B2. The differential buffer circuit 14a outputs the second output signal OUT up-converted from the gain G1 into the gain G2 and from the bandwidth B1 into the bandwidth B2. By the differential buffer circuit 14a, the gain G3 and the bandwidth B3 of the first output signal OUTB are decreased, but the gain G1 and the bandwidth B1 of the second output signal OUT are increased. Accordingly, the performance of the differential buffer circuit 14a is improved because of the increased gain G2 and bandwidth B2 of the second output signal OUT.

According to some implementations, the transmitter 11 (see FIG. 1), the receiver 12 (see FIG. 1), and the channel 13 (see FIG. 1) may support pulse amplitude modulation level 4 (PAM4) signaling for converting two-bit streams into a single multi-level signal having four levels. The transmitter 11 may include a PAM4 encoder configured to convert user data (sometimes, referred to as original data) to be transmitted to the receiver 12 into PAM4 symbols, and the PAM4 encoder may include hardware, firmware, or software for forming an encoding circuit, or a look-up table implemented by a combination thereof. The transmitter 11 may include an output driver configured to drive the PAM4 symbols to the channel 13 and transmit the PAM4 symbols to the receiver 12 (see FIG. 1) through the channel 13. The receiver 12 may include a clock data recovery (CDR) circuit configured to receive the PAM4 symbols through the channel 13 and a PAM4 decoder configured to decode the received PAM4 symbols. The CDR circuit may generate a clock signal synchronized with the PAM4 symbols from the PAM4 symbols transmitted through the channel 13 and sample the PAM4 symbols based on the clock signal. The CDR circuit may determine the levels of the PAM4 symbols based on a comparison result between each of first to third reference voltage levels with the PAM4 symbols in response to first to third clock signals and provide output data including first to third determination values to the PAM4 decoder. The CDR circuit may employ the differential buffer circuit 14a to perform a comparison function between each of the first to third reference voltage levels with the PAM4 symbols. The PAM4 decoder may decode the output data of the CDR circuit to recover data bursts of two-bit streams, i.e., user data. The PAM4 decoder may include hardware, firmware, or software for forming a decoding circuit, or a look-up table implemented by a combination thereof. The look-up table of the PAM4 decoder may be the same as the look-up table of the PAM4 encoder.

According to some implementations, the receiver 12 (see FIG. 1) including the differential buffer circuit 14b of FIG. 4B may be employed in a memory device (e.g., flash memory or dynamic random access memory (DRAM). The differential buffer circuit 14b may use a differential transistor pair (the first transistor M41 and the second transistor M42) configured to receive a complementary input signal/N instead of the reference voltage VREF of the differential buffer circuit 14a and output a first output signal OUTB and a second output signal OUT. The input signal IN and the complementary input signal/N may indicate a clock signal including signals RE_t and RE_c and signals DQS_t and DQS_c used for data providing timing related to data. The clock signal is complementary when a rising edge of a first clock signal and a falling edge of a second clock signal simultaneously occur and when a rising edge of the second clock signal and a falling edge of the first clock signal simultaneously occur.

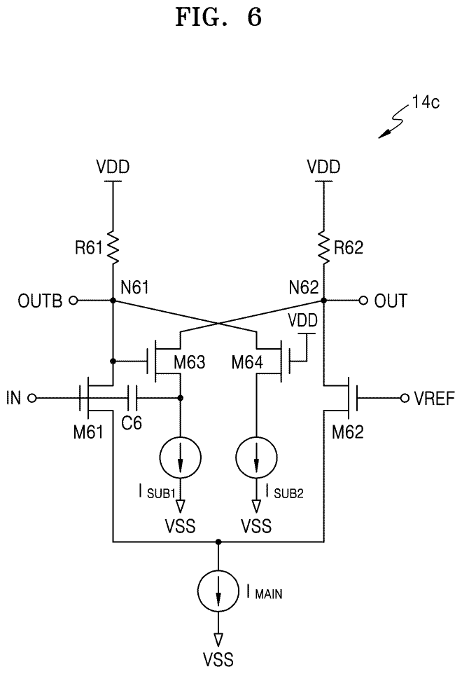

FIG. 6 is a circuit diagram illustrating a differential buffer circuit 14c according to implementations.

Referring to FIG. 6, the differential buffer circuit 14c may include a pair of output signal nodes, i.e., first and second output nodes N61 and N62, for outputting a response to the input signal IN, wherein the first output node N61 outputs a first output signal OUTB of the differential buffer circuit 14c, and the second output node N62 outputs a second output signal OUT of the differential buffer circuit 14c. To output the first output signal OUTB and the second output signal OUT having the same gain and bandwidth, the differential buffer circuit 14c may include the first current source I_{MAIN}, the second current source I_{SUB1}, the third current source I_{SUB2}, a capacitor C6, a first transistor M61, a second transistor M62, a third transistor M63, a fourth transistor M64, a first resistor R61, and a second resistor R62.

The first current source I_{MAIN}, the second current source I_{SUB1}, and the third current source I_{SUB2} may be connected to a ground voltage VSS and provide a bias current for driving the differential buffer circuit 14c. The first resistor R61 may be connected between the power source voltage VDD line and the first output node N61, and the second resistor R62 may be connected between the power source voltage VDD line and the second output node N62. A first end of the capacitor C6 may receive the input signal IN, and a second end of the capacitor C6 may be connected to a first end of the second current source I_{SUB1} and a second end of the third transistor M63.

A first end of the first transistor M61 may be connected to the first output node N61, a second end of the first transistor M61 may be connected to a first end of the first current source I_{MAIN}, and a control end of the first transistor M61 may receive the input signal IN. A first end of the second transistor M62 may be connected to the second output node N62, a second end of the second transistor M62 may be connected to the first end of the first current source I_{MAIN}, and a control end of the second transistor M62 may be connected to the reference voltage VREF line. A first end of the third transistor M63 may be connected to the second output node N62, a second end of the third transistor M63 may be connected to the first end of the second current source I_{SUB1} and the second end of the capacitor C6, and a control end of the third transistor M63 may be connected to the first output node N61. A first end of the fourth transistor M64 may be connected to the first output node N61, a second end of the fourth transistor M64 may be connected to a first end of the third current source I_{SUB2}, and a control end of the fourth transistor M64 may be connected to the power source voltage VDD line. The first to fourth transistors M61, M62, M63, and M64 may include NMOS transistors. According to some implementations, the first to fourth transistors M61, M62, M63, and M64 may include PMOS transistors. The first end of the first current source I_{MAIN} may be connected to the second ends of the first transistor M61 and the second transistor M62, and a second end of the first current source I_{MAIN} may be connected to the ground voltage VSS line. The first end of the second current source I_{SUB1} may be connected to the second end of the third transistor M63 and the second end of the capacitor C6, and a second end of the second current source I_{SUB1} may be connected to the ground voltage VSS line. The first end of the third current source I_{SUB2} may be connected to the second end of the fourth transistor M64, and a second end of the third current source I_{SUB2} may be connected to the ground voltage VSS line.

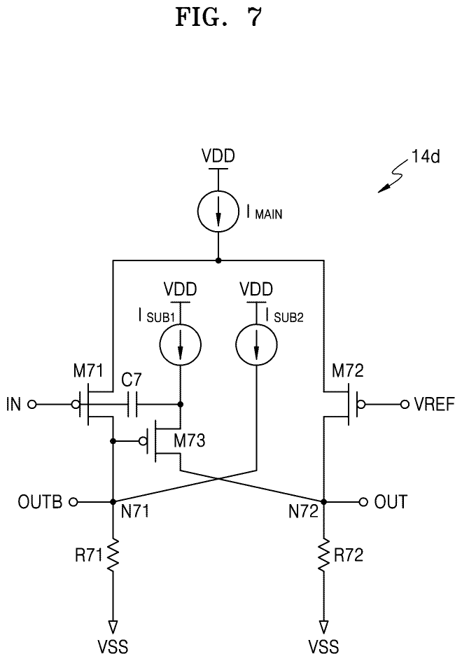

FIG. 7 is a circuit diagram illustrating a differential buffer circuit 14d according to some implementations.

Referring to FIG. 7, the differential buffer circuit 14d may include a pair of output signal nodes, i.e., first and second output nodes N71 and N72, for outputting a response to the input signal IN, wherein the first output node N71 outputs a first output signal OUTB of the differential buffer circuit 14d, and the second output node N72 outputs a second output signal OUT of the differential buffer circuit 14d. To output the first output signal OUTB and the second output signal OUT having the same gain and bandwidth, the differential buffer circuit 14d may include the first current source I_{MAIN}, the second current source I_{SUB1}, the third current source I_{SUB2}, a capacitor C7, a first transistor M71, a second transistor M72, a third transistor M73, a first resistor R71, and a second resistor R72.

The first current source I_{MAIN}, the second current source I_{SUB1}, and the third current source I_{SUB2} may be connected to the power source voltage VDD and provide a bias current for driving the differential buffer circuit 14d. A first end of the first current source I_{MAIN} may be connected to the power source voltage VDD line, and a second end of the first current source I_{MAIN} may be connected to first ends of the first transistor M71 and the second transistor M72. A first end of the second current source I_{SUB1} may be connected to the power source voltage VDD line, and a second end of the second current source I_{SUB1} may be connected to a first end of the third transistor M73. A first end of the third current source I_{SUB2} may be connected to the power source voltage VDD line, and a second end of the third current source I_{SUB2} may be connected to the first output node N71.

A first end of the capacitor C7 may receive the input signal IN, and a second end of the capacitor C7 may be connected to the second end of the second current source I_{SUB1} and the first end of the third transistor M73. The first end of the first transistor M71 may be connected to the second end of the first current source I_{MAIN}, a second end of the first transistor M71 may be connected to the first output node N71, and a control end of the first transistor M71 may receive the input signal IN. The first end of the second transistor M72 may be connected to the second end of the first current source I_{MAIN}, a second end of the second transistor M72 may be connected to the second output node N72, and a control end of the second transistor M72 may be connected to the reference voltage VREF line. The first end of the third transistor M73 may be connected to the second end of the second current source I_{SUB1} and the second end of the capacitor C7, a second end of the third transistor M73 may be connected to the second output node N72, and a control end of the third transistor M73 may be connected to the first output node N71. The first to third transistors M71, M72, and M73 may include PMOS transistors. The first resistor R71 may be connected between the first output node N71 and the ground voltage VSS line, and the second resistor R72 may be connected between the second output node N72 and the ground voltage VSS line.

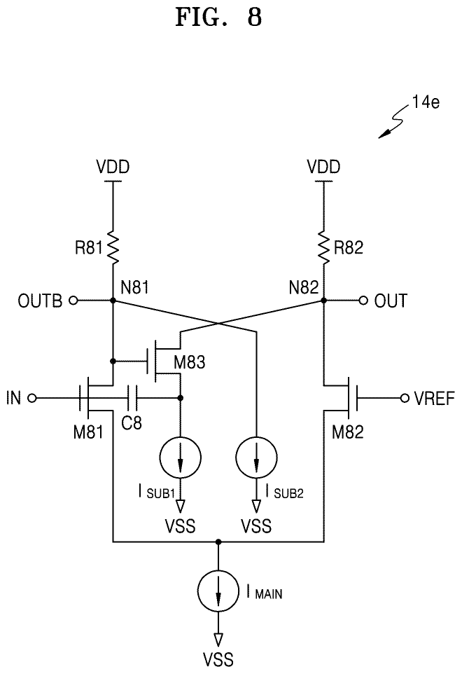

FIG. 8 is a circuit diagram illustrating a differential buffer circuit 14e according to some implementations.

Referring to FIG. 8, the differential buffer circuit 14e may include a pair of output signal nodes, i.e., first and second output nodes N81 and N82, for outputting a response to the input signal IN, wherein the first output node N81 outputs a first output signal OUTB of the differential buffer circuit 14e, and the second output node N82 outputs a second output signal OUT of the differential buffer circuit 14e. To output the first output signal OUTB and the second output signal OUT having the same gain and bandwidth, the differential buffer circuit 14e may include the first current source I_{MAIN}, the second current source I_{SUB1}, the third current source I_{SUB2}, a capacitor C8, a first transistor M81, a second transistor M82, a third transistor M83, a first resistor R81, and a second resistor R82.

The first current source I_{MAIN}, the second current source I_{SUB1}, and the third current source I_{SUB2} may be connected to the ground voltage VSS and provide a bias current for driving the differential buffer circuit 14e. The first resistor R81 may be connected between the power source voltage VDD line and the first output node N81, and the second resistor R82 may be connected between the power source voltage VDD line and the second output node N82. A first end of the capacitor C8 may receive the input signal IN, and a second end of the capacitor C8 may be connected to a first end of the second current source I_{SUB1} and a second end of the third transistor M83.

A first end of the first transistor M81 may be connected to the first output node N81, a second end of the first transistor M81 may be connected to a first end of the first current source I_{MAIN}, and a control end of the first transistor M81 may receive the input signal IN. A first end of the second transistor M82 may be connected to the second output node N82, a second end of the second transistor M82 may be connected to the first end of the first current source I_{MAIN}, and a control end of the second transistor M82 may be connected to the reference voltage VREF line. A first end of the third transistor M83 may be connected to the second output node N82, the second end of the third transistor M83 may be connected to the first end of the second current source I_{SUB1} and the second end of the capacitor C8, and a control end of the third transistor M83 may be connected to the first output node N81. The first to third transistors M81, M82, and M83 may include NMOS transistors. According to some implementations, the first to third transistors M81, M82, and M83 may include PMOS transistors.

The first end of the first current source I_{MAIN} may be connected to the second ends of the first transistor M81 and the second transistor M82, and a second end of the first current source I_{MAIN} may be connected to the ground voltage VSS line. The first end of the second current source I_{SUB1} may be connected to the second end of the third transistor M83 and the second end of the capacitor C8, and a second end of the second current source I_{SUB1} may be connected to the ground voltage VSS line. The first end of the third current source I_{SUB2} may be connected to the first output node N81, and a second end of the third current source I_{SUB2} may be connected to the ground voltage VSS line.

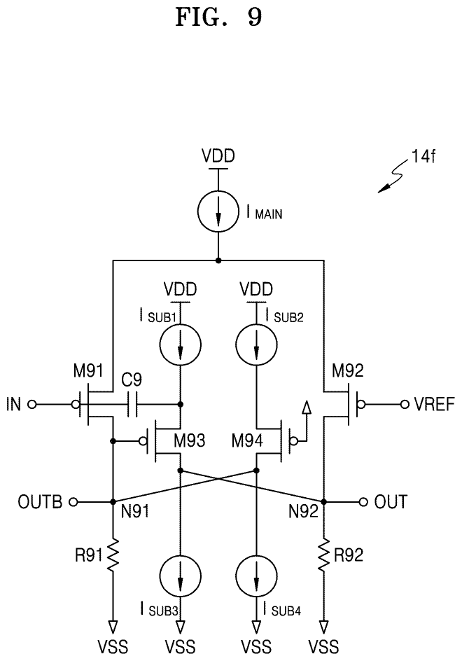

FIG. 9 is a circuit diagram illustrating a differential buffer circuit 14f according to some implementations.

Referring to FIG. 9, the differential buffer circuit 14f may include a pair of output signal nodes, i.e., first and second output nodes N91 and N92, for outputting a response to the input signal IN, wherein the first output node N91 outputs a first output signal OUTB of the differential buffer circuit 14f, and the second output node N92 outputs a second output signal OUT of the differential buffer circuit 14f To output the first output signal OUTB and the second output signal OUT having the same gain and bandwidth, the differential buffer circuit 14f may include the first current source I_{MAIN}, the second current source I_{SUB1}, the third current source I_{SUB2}, a fourth current source I_{SUB3}, a fifth current source I_{SUB4}, a capacitor C9, a first transistor M91, a second transistor M92, a third transistor M93, a fourth transistor M94, a first resistor R91, and a second resistor R92.

The first current source I_{MAIN}, the second current source I_{SUB1}, and the third current source I_{SUB2} may be connected to the power source voltage VDD, the fourth current source I_{SUB3} and the fifth current source I_{SUB4} may be connected to the ground voltage VSS, and the first to fifth current sources I_{MAIN}, I_{SUB1}, I_{SUB2}, I_{SUB3}, and I_{SUB4} may provide a bias current for driving the differential buffer circuit 14f A first end of the first current source I_{MAIN} may be connected to the power source voltage VDD line, and a second end of the first current source I_{MAIN} may be connected to first ends of the first transistor M91 and the second transistor M92. A first end of the second current source I_{SUB1} may be connected to the power source voltage VDD line, and a second end of the second current source I_{SUB1} may be connected to a first end of the third transistor M93. A first end of the third current source I_{SUB2} may be connected to the power source voltage VDD line, and a second end of the third current source I_{SUB2} may be connected to a first end of the fourth transistor M94.

A first end of the capacitor C9 may receive the input signal IN, and a second end of the capacitor C9 may be connected to the second end of the second current source I_{SUB1} and the first end of the third transistor M93. The first end of the first transistor M91 may be connected to the second end of the first current source I_{MAIN}, a second end of the first transistor M91 may be connected to the first output node N91, and a control end of the first transistor M91 may receive the input signal IN. The first end of the second transistor M92 may be connected to the second end of the first current source I_{MAIN}, a second end of the second transistor M92 may be connected to the second output node N92, and a control end of the second transistor M92 may be connected to the reference voltage VREF line. The first end of the third transistor M93 may be connected to the second end of the second current source I_{SUB1} and the second end of the capacitor C9, a second end of the third transistor M93 may be connected to the second output node N92 and a first end of the fourth current source I_{SUB3}, and a control end of the third transistor M93 may be connected to the first output node N91. The first end of the fourth transistor M94 may be connected to the second end of the third current source I_{SUB2}, a second end of the fourth transistor M94 may be connected to the first output node N91 and a first end of the fifth current source I_{SUB4}, and a control end of the fourth transistor M94 may be connected to the ground voltage VSS line. The first to fourth transistors M91, M92, M93, and M94 may include PMOS transistors. According to some implementations, the first to fourth transistors M91, M92, M93, and M94 may include NMOS transistors.

The first resistor R91 may be connected between the first output node N91 and the ground voltage VSS line, and the second resistor R92 may be connected between the second output node N92 and the ground voltage VSS line. The first end of the fourth current source I_{SUB3} may be connected to the second output node N92, and a second end of the fourth current source I_{SUB3} may be connected to the ground voltage VSS line. The first end of the fifth current source I_{SUB4} may be connected to the first output node N91, and a second end of the fifth current source I_{SUB4} may be connected to the ground voltage VSS line.

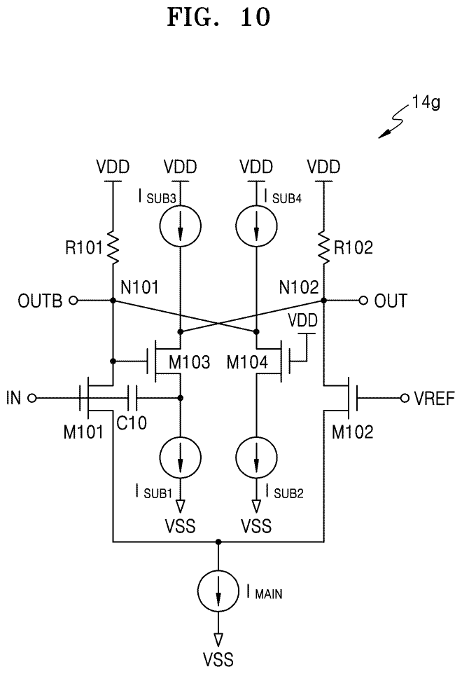

FIG. 10 is a circuit diagram illustrating a differential buffer circuit 14g according to some implementations.

Referring to FIG. 10, the differential buffer circuit 14g may include a pair of output signal nodes, i.e., first and second output nodes N101 and N102, for outputting a response to the input signal IN, wherein the first output node N101 outputs a first output signal OUTB of the differential buffer circuit 14g, and the second output node N102 outputs a second output signal OUT of the differential buffer circuit 14g. To output the first output signal OUTB and the second output signal OUT having the same gain and bandwidth, the differential buffer circuit 14g may include the first current source I_{MAIN}, the second current source I_{SUB1}, the third current source I_{SUB2}, the fourth current source I_{SUB3}, the fifth current source I_{SUB4}, a capacitor C10, a first transistor M101, a second transistor M102, a third transistor M103, a fourth transistor M104, a first resistor R101, and a second resistor R102.

The first current source I_{MAIN}, the second current source I_{SUB1}, and the third current source I_{SUB2} may be connected to the ground voltage VSS, the fourth current source I_{SUB3} and the fifth current source I_{SUB4} may be connected to the power source voltage VDD, and the first to fifth current sources I_{MAIN}, I_{SUB1}, I_{SUB2}, I_{SUB3}, and I_{SUB4} may provide a bias current for driving the differential buffer circuit 14g. The first resistor R101 may be connected between the power source voltage VDD line and the first output node N101, and the second resistor R102 may be connected between the power source voltage VDD line and the second output node N102. A first end of the fourth current source I_{SUB3} may be connected to the power source voltage VDD line, and a first end of the fifth current source I_{SUB4} may be connected to the power source voltage VDD line. A first end of the capacitor C10 may receive the input signal IN, and a second end of the capacitor C10 may be connected to a first end of the second current source I_{SUB1} and a second end of the third transistor M103.

A first end of the first transistor M101 may be connected to the first output node N101, a second end of the first transistor M101 may be connected to a first end of the first current source I_{MAIN}, and a control end of the first transistor M101 may receive the input signal IN. A first end of the second transistor M102 may be connected to the second output node N102, a second end of the second transistor M102 may be connected to the first end of the first current source I_{MAIN}, and a control end of the second transistor M102 may be connected to the reference voltage VREF line. A first end of the third transistor M103 may be connected to the second output node N102 and a second end of the fourth current source I_{SUB3}, a second end of the third transistor M103 may be connected to the first end of the second current source I_{SUB1} and the second end of the capacitor C10, and a control end of the third transistor M103 may be connected to the first output node N101. A first end of the fourth transistor M104 may be connected to the first output node N101 and a second end of the fifth current source I_{SUB4}, a second end of the fourth transistor M104 may be connected to a first end of the third current source I_{SUB2}, and a control end of the fourth transistor M104 may be connected to the power source voltage VDD line. The first to fourth transistors M101, M102, M103, and M104 may include NMOS transistors. According to some implementations, the first to fourth transistors M101, M102, M103, and M104 may include PMOS transistors.

The first end of the first current source I_{MAIN} may be connected to the second ends of the first transistor M101 and the second transistor M102, and a second end of the first current source I_{MAIN} may be connected to the ground voltage VSS line. The first end of the second current source I_{SUB1} may be connected to the second end of the third transistor M103 and the second end of the capacitor C10, and a second end of the second current source I_{SUB1} may be connected to the ground voltage VSS line. The first end of the third current source I_{SUB2} may be connected to the second end of the fourth transistor M104, and a second end of the third current source I_{SUB2} may be connected to the ground voltage VSS line.

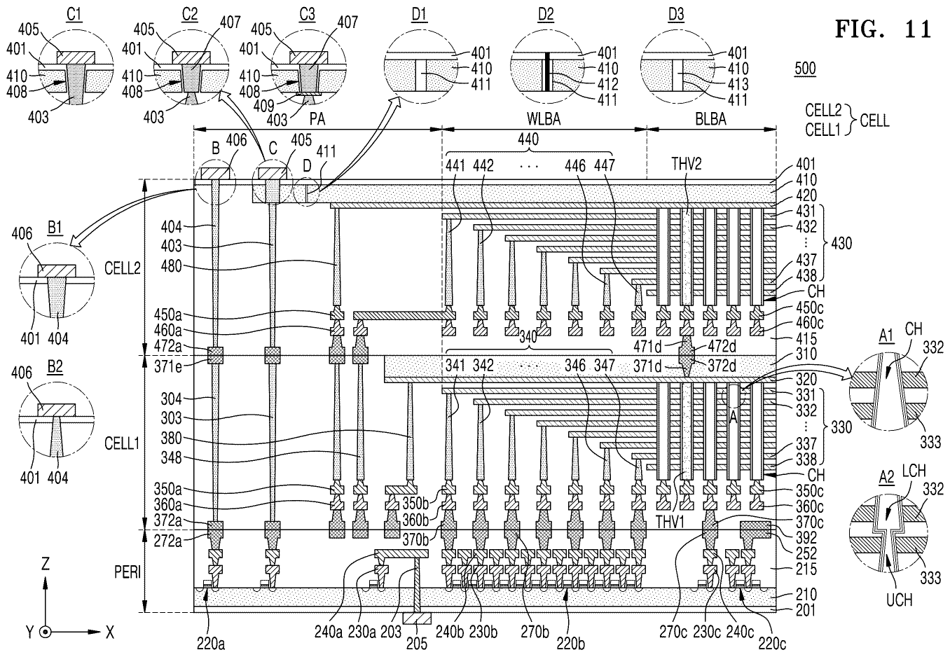

FIG. 11 is a cross-sectional view of a memory device 500 having a bonding vertical NAND (B-VNAND) structure including a receiver circuit according to some implementations.

Referring to FIG. 11, the memory device 500 may have a chip-to-chip (C2C) structure. Herein, the C2C structure may indicate that at least one upper chip including a cell area CELL and a lower chip including a peripheral circuit area PERI are individually manufactured and then the at least one upper chip is connected to the lower chip in a bonding manner. For example, the bonding manner may indicate a manner of electrically or physically connecting a bonding metal pattern formed on the uppermost metal layer of the at least one upper chip to a bonding metal pattern formed on the uppermost metal layer of the lower chip. For example, when the bonding metal patterns are formed of copper (Cu), the bonding manner may be a Cu—Cu bonding manner. As another example, the bonding metal patterns may be formed of aluminum (Al) or tungsten (W).

The memory device 500 may include the at least one upper chip including the cell area CELL. For example, as shown in FIG. 11, the memory device 500 may include two upper chips. However, this is only illustrative, and the number of upper chips is not limited thereto. When the memory device 500 includes two upper chips, the memory device 500 may be manufactured by individually manufacturing a first upper chip including a first cell area CELL1, a second upper chip including a second cell area CELL2, and the lower chip including the peripheral circuit area PERI and then connecting the first upper chip, the second upper chip, and the lower chip to each other in the bonding manner. The first upper chip may be upside down and connected to the lower chip in the bonding manner, and the second upper chip may also be upside down and connected to the first upper chip in the bonding manner. In the description below, upper portions and lower portions of the first and second upper chips are defined based on before the first upper chip and the second upper chip are upside down. That is, an upper portion of the lower chip indicates an upper portion defined based on the +Z-axis direction, and the upper portion of each of the first and second upper chips indicates an upper portion defined based on the −Z-axis direction. However, this is only illustrative, and only any one of the first upper chip and the second upper chip may be upside down and connected to the lower chip or the first upper chip in the bonding manner.

Each of the peripheral circuit area PERI and the first and second cell areas CELL1 and CELL2 of the memory device 500 may include an outer pad bonding area PA, a word line bonding area WLBA, and a bit line bonding area BLBA.

The peripheral circuit area PERI may include a first substrate 210 and a plurality of circuit devices 220a, 220b, and 220c formed on the first substrate 210. An interlayer insulating layer 215 including one or more insulating layers may be provided on the plurality of circuit devices 220a, 220b, and 220c, and a plurality of metal wirings connecting the plurality of circuit devices 220a, 220b, and 220c may be provided inside the interlayer insulating layer 215. For example, the plurality of metal wirings may include first metal wirings 230a, 230b, and 230c respectively connected to the plurality of circuit devices 220a, 220b, and 220c and second metal wirings 240a, 240b, and 240c respectively formed on the first metal wirings 230a, 230b, and 230c. The plurality of metal wirings may be formed of at least one of various conductive materials. For example, the first metal wirings 230a, 230b, and 230c may be formed of W having a relatively high electrical specific resistance, and the second metal wirings 240a, 240b, and 240c may be formed of Cu having a relatively low electrical specific resistance.

In the specification, although only the first metal wirings 230a, 230b, and 230c and the second metal wirings 240a, 240b, and 240c are shown and described, the specification is not limited thereto, and at least one additional metal wiring may be further formed on the second metal wirings 240a, 240b, and 240c. In this case, the second metal wirings 240a, 240b, and 240c may be formed of Al. In addition, at least a portion of the at least one additional metal wiring formed on the second metal wirings 240a, 240b, and 240c may be formed of Cu or the like having an electrical specific resistance lower than that of Al.

The interlayer insulating layer 215 may be disposed on the first substrate 210 and include an insulating material, such as silicon oxide or silicon nitride.

Each of the first and second cell areas CELL1 and CELL2 may include at least one memory block. The first cell area CELL1 may include a second substrate 310 and a common source line 320. A plurality of word lines 330 (including 331 to 338) may be stacked above the second substrate 310 in a direction (the Z-axis direction) perpendicular to the upper surface of the second substrate 310. String select lines and a ground select line may be disposed above and under the plurality of word lines 330, and the plurality of word lines 330 may be disposed between the string select lines and the ground select line. Likewise, the second cell area CELL2 may include a third substrate 410 and a common source line 420, and a plurality of word lines 430 (including 431 to 438) may be stacked in a direction (the Z-axis direction) perpendicular to the upper surface of the third substrate 410. Each of the second substrate 310 and the third substrate 410 may be formed of various materials and may be, for example, a silicon substrate, a silicon-germanium substrate, or a substrate having a monocrystalline epitaxial layer grown on a monocrystalline silicon substrate. A plurality of channel structures CH may be formed in each of the first and second cell areas CELL1 and CELL2.

In some implementations, as shown in a portion A1, a channel structure CH may be provided to the bit line bonding area BLBA, extend in the direction perpendicular to the upper surface of the second substrate 310, and pass through the plurality of word lines 330, the string select lines, and the ground select line. The channel structure CH may include a data storage layer, a channel layer, a buried insulating layer, and the like. The channel layer may be electrically connected to a first metal wiring 350c and a second metal wiring 360c in the bit line bonding area BLBA. For example, the second metal wiring 360c may be a bit line and be connected to the channel structure CH via the first metal wiring 350c. The bit line 360c may extend in a first direction (the Y-axis direction) parallel to the upper surface of the second substrate 310.

In some implementations, as shown in a portion A2, the channel structure CH may include a lower channel LCH and an upper channel UCH connected to each other. For example, the channel structure CH may be formed through a process on the lower channel LCH and a process on the upper channel UCH. The lower channel LCH may extend in the direction perpendicular to the upper surface of the second substrate 310 and pass through the common source line 320 and the word lines 331 and 332 at a lower side. The lower channel LCH may include the data storage layer, the channel layer, and the buried insulating layer and be connected to the upper channel UCH. The upper channel UCH may pass through the word lines 333 to 338 at an upper side. The upper channel UCH may include the data storage layer, the channel layer, and the buried insulating layer, and the channel layer of the upper channel UCH may be electrically connected to the first metal wiring 350c and the second metal wiring 360c. As the length of a channel is long, it may be difficult to form the channel having a constant width due to a cause according to a process. The memory device 500 according to some implementations may have a channel having width uniformity improved through the lower channel LCH and the upper channel UCH formed in sequential processes.

As shown in the portion A2, when the channel structure CH is formed with the lower channel LCH and the upper channel UCH, a word line adjacent to the boundary of the lower channel LCH and the upper channel UCH may be a dummy word line. For example, the word line 332 and the word line 333 adjacent to the boundary of the lower channel LCH and the upper channel UCH may be dummy word lines. In this case, data may not be stored in memory cells connected to the dummy word lines. Alternatively, the number of pages corresponding to the memory cells connected to the dummy word lines may be less than the number of pages corresponding to memory cells connected to normal word lines. A voltage level applied to a dummy word line may be different from a voltage level applied to a normal word line, and accordingly, an effect of a nonuniform channel width between the lower channel LCH and the upper channel UCH on an operation of a memory device may be reduced.

In the portion A2, the number of word lines, e.g., the word lines 331 and 332, through which the lower channel LCH passes is less than the number of word lines, e.g., the word lines 333 to 338, through which the upper channel UCH passes. However, this is only illustrative, and the present disclosure is not limited thereto. As another example, the number of word lines through which the lower channel LCH passes may be greater than or equal to the number of word lines through which the upper channel UCH passes. In addition, the structure and connection relationship of the channel structure CH disposed in the first cell area CELL1 may be applied to the channel structure CH disposed in the second cell area CELL2 in the same manner.

In the bit line bonding area BLBA, a first through electrode THV1 may be provided in the first cell area CELL1, and a second through electrode THV2 may be provided in the second cell area CELL2. As shown in FIG. 11, the first through electrode THV1 may pass through the common source line 320 and the plurality of word lines 330. However, this is illustrative, and the first through electrode THV1 may further pass through the second substrate 310. The first through electrode THV1 may include a conductive material. Alternatively, the first through electrode THV1 may include a conductive material surrounded by an insulating material. The second through electrode THV2 may also be provided in the same shape and structure as those of the first through electrode THV1.

In some implementations, the first through electrode THV1 may be electrically connected to the second through electrode THV2 via a first through metal pattern 372d and a second through metal pattern 472d. The first through metal pattern 372d may be formed at a lower end of the first upper chip including the first cell area CELL1, and the second through metal pattern 472d may be formed at an upper end of the second upper chip including the second cell area CELL2. The first through electrode THV1 may be electrically connected to the first metal wiring 350c and the second metal wiring 360c. A lower via 371d may be formed between the first through electrode THV1 and the first through metal pattern 372d, and an upper via 471d may be formed between the second through electrode THV2 and the second through metal pattern 472d. The first through metal pattern 372d may be connected to the second through metal pattern 472d in the bonding manner.

In addition, in the bit line bonding area BLBA, an upper metal pattern 252 may be formed on the uppermost metal layer of the peripheral circuit area PERI, and an upper metal pattern 392 in the same shape as that of the upper metal pattern 252 on the uppermost metal layer of the first cell area CELL1. The upper metal pattern 392 of the first cell area CELL1 may be electrically connected to the upper metal pattern 252 of the peripheral circuit area PERI in the bonding manner. In the bit line bonding area BLBA, the bit line 360c may be electrically connected to a page buffer included in the peripheral circuit area PERI. For example, some of the circuit devices 220c of the peripheral circuit area PERI may provide page buffers, and the bit line 360c may be electrically connected to some of the circuit devices 220c, which provide the page buffers, via upper bonding metals 370c of the first cell area CELL1 and upper bonding metals 270c of the peripheral circuit area PERI.

Referring to FIG. 11, in the word line bonding area WLBA, the plurality of word lines 330 of the first cell area CELL1 may extend in a second direction (the X-axis direction) parallel to the upper surface of the second substrate 310 and be connected to a plurality of cell contact plugs 340 (including 341 to 347), respectively. A first metal wiring 350b and a second metal wiring 360b may be sequentially connected onto each of the plurality of cell contact plugs 340 respectively connected to the word lines 331 to 337. In the word line bonding area WLBA, each of the plurality of cell contact plugs 340 may be connected to the peripheral circuit area PERI via an upper bonding metal 370b of the first cell area CELL1 and an upper bonding metal 270b of the peripheral circuit area PERI.

The plurality of cell contact plugs 340 may be electrically connected to row decoders included in the peripheral circuit area PERI. For example, some of the circuit devices 220b of the peripheral circuit area PERI may provide the row decoders, and the plurality of cell contact plugs 340 may be electrically connected to some of the circuit devices 220b, which provide the row decoders, via the upper bonding metal 370b of the first cell area CELL1 and the upper bonding metal 270b of the peripheral circuit area PERI. In some implementations, the operating voltage of some of the circuit devices 220b providing the row decoders may be different from the operating voltage of some of the circuit devices 220c providing the page buffers. For example, the operating voltage of some of the circuit devices 220b providing the row decoders may be higher than the operating voltage of some of the circuit devices 220c providing the page buffers.

Likewise, in the word line bonding area WLBA, the plurality of word lines 430 of the second cell area CELL2 may extend in the second direction (the X-axis direction) parallel to the upper surface of the third substrate 410 and be connected to a plurality of cell contact plugs 440 (including 441 to 447), respectively. Each of the plurality of cell contact plugs 440 may be connected to the peripheral circuit area PERI via an upper metal pattern of the second cell area CELL2, a lower metal pattern and an upper metal pattern of the first cell area CELL1, and a cell contact plug 348.

In the word line bonding area WLBA, the upper bonding metal 370b may be formed in the first cell area CELL1, and the upper bonding metal 270b may be formed in the peripheral circuit area PERI. The upper bonding metal 370b of the first cell area CELL1 may be electrically connected to the upper bonding metal 270b of the peripheral circuit area PERI in the bonding manner. The upper bonding metal 370b and the upper bonding metal 270b may be formed of Al, Cu, W, or the like.

In the outer pad bonding area PA, a lower metal pattern 371e may be formed at a lower portion of the first cell area CELL1, and an upper metal pattern 472a may be formed at an upper portion of the second cell area CELL2. In the outer pad bonding area PA, the lower metal pattern 371e of the first cell area CELL1 may be connected to the upper metal pattern 472a of the second cell area CELL2 in the bonding manner. Likewise, an upper metal pattern 372a may be formed at an upper portion of the first cell area CELL1, and an upper metal pattern 272a may be formed at an upper portion of the peripheral circuit area PERI. The upper metal pattern 372a of the first cell area CELL1 may be connected to the upper metal pattern 272a of the peripheral circuit area PERI in the bonding manner.

Common source line contact plugs 380 and 480 may be disposed in the outer pad bonding area PA. The common source line contact plugs 380 and 480 may be formed of a conductive material, such as a metal, a metal compound, or doped polysilicon. The common source line contact plug 380 of the first cell area CELL1 may be electrically connected to the common source line 320, and the common source line contact plug 480 of the second cell area CELL2 may be electrically connected to the common source line 420. A first metal wiring 350a and a second metal wiring 360a may be sequentially stacked on the common source line contact plug 380 of the first cell area CELL1, and a first metal wiring 450a and a second metal wiring 460a may be sequentially stacked on the common source line contact plug 480 of the second cell area CELL2.

Input/output (110) pads, e.g., first to third I/O pads 205, 405, and 406, may be disposed in the outer pad bonding area PA. Referring to FIG. 11, a lower insulating layer 201 may cover the lower surface of the first substrate 210, and the first I/O pad 205 may be formed on the lower insulating layer 201. The first I/O pad 205 may be connected to at least one of the plurality of circuit devices 220a disposed in the peripheral circuit area PERI via a first I/O contact plug 203 and separated from the first substrate 210 by the lower insulating layer 201. In addition, a side insulating layer may be disposed between the first I/O contact plug 203 and the first substrate 210 to electrically isolate the first I/O contact plug 203 from the first substrate 210.

An upper insulating layer 401 covering the upper surface of the third substrate 410 may be formed on the third substrate 410. The second I/O pad 405 and/or the third I/O pad 406 may be disposed on the upper insulating layer 401. The second I/O pad 405 may be connected to at least one of the plurality of circuit devices 220a disposed in the peripheral circuit area PERI via second I/O contact plugs 403 and 303, and the third I/O pad 406 may be connected to at least one of the plurality of circuit devices 220a disposed in the peripheral circuit area PERI via third I/O contact plugs 404 and 304.

In some implementations, the third substrate 410 may not be disposed in a region with an I/O contact plug. For example, as shown in a portion B, the third I/O contact plug 404 may be separated from the third substrate 410 in a direction parallel to the upper surface of the third substrate 410 and connected to the third I/O pad 406 by passing through an interlayer insulating layer 415 of the second cell area CELL2. In this case, the third I/O contact plug 404 may be formed in various processes.

In some implementations, as shown in a portion B1, the third I/O contact plug 404 may extend in a third direction (the Z-axis direction) and be formed to have a diameter gradually increasing toward the upper insulating layer 401. That is, unlike the portion A1 in which the channel structure CH is formed to have a diameter gradually decreasing toward the upper insulating layer 401, the third I/O contact plug 404 may be formed to have a diameter gradually increasing toward the upper insulating layer 401. For example, the third I/O contact plug 404 may be formed after the second cell area CELL2 is bonded to the first cell area CELL1 in the bonding manner.

Alternatively, in some implementations, as shown in a portion B2, the third I/O contact plug 404 may extend in the third direction (the Z-axis direction) and be formed to have a diameter gradually decreasing toward the upper insulating layer 401. That is, like the channel structure CH, the third I/O contact plug 404 may be formed to have a diameter gradually decreasing toward the upper insulating layer 401. For example, the third I/O contact plug 404 may be formed together with the plurality of cell contact plugs 440 before the second cell area CELL2 is bonded to the first cell area CELL1.

In other implementations, an I/O contact plug may be disposed to overlap the third substrate 410. For example, as shown in a portion C, the second I/O contact plug 403 may be formed by passing through the interlayer insulating layer 415 of the second cell area CELL2 in the third direction (the Z-axis direction) and electrically connected to the second I/O pad 405 by passing through the third substrate 410. In this case, a connection structure between the second I/O contact plug 403 and the second I/O pad 405 may be implemented in various ways.

In some implementations, as shown in a portion C1, an opening portion 408 passing through the third substrate 410 may be formed, and the second I/O contact plug 403 may be directly connected to the second I/O pad 405 by passing through the opening portion 408 formed in the third substrate 410. In this case, as shown in the portion C1, the second I/O contact plug 403 may be formed to have a diameter gradually increasing toward the second I/O pad 405. However, this is illustrative, and the second I/O contact plug 403 may be formed to have a diameter gradually decreasing toward the second I/O pad 405.

In some implementations, as shown in a portion C2, the opening portion 408 passing through the third substrate 410 may be formed, and a contact 407 may be formed inside the opening portion 408. One end portion of the contact 407 may be connected to the second I/O pad 405, and the other end portion of the contact 407 may be connected to the second I/O contact plug 403. Accordingly, the second I/O contact plug 403 may be electrically connected to the second I/O pad 405 via the contact 407 inside the opening portion 408. In this case, as shown in the portion C2, the contact 407 may be formed to have a diameter gradually increasing toward the second I/O pad 405, and the second I/O contact plug 403 may be formed to have a diameter gradually decreasing toward the second I/O pad 405. For example, the second I/O contact plug 403 may be formed together with the plurality of cell contact plugs 440 before the second cell area CELL2 is bonded to the first cell area CELL1, and the contact 407 may be formed after the second cell area CELL2 is bonded to the first cell area CELL1.

Alternatively, in some implementations, as shown in a portion C3, compared to the portion C2, a stopper 409 may be further formed on the upper surface of the opening portion 408 of the third substrate 410. The stopper 409 may be a metal wiring formed on the same layer as the common source line 420. However, this is illustrative, and the stopper 409 may be a metal wiring formed on the same layer as at least one of the plurality of word lines 430. The second I/O contact plug 403 may be electrically connected to the second I/O pad 405 via the contact 407 and the stopper 409.

Similarly to the second and third I/O contact plugs 403 and 404 of the second cell area CELL2, each of the second and third I/O contact plugs 303 and 304 of the first cell area CELL1 may be formed to have a diameter gradually decreasing or increasing toward the lower metal pattern 371e.

According to implementations, a slit 411 may be formed in the third substrate 410. For example, the slit 411 may be formed at a random location of the outer pad bonding area PA. For example, as shown in a portion D, the slit 411 may be located between the second I/O pad 405 and the plurality of cell contact plugs 440 in a plan view. However, this is illustrative, and in a plan view, the slit 411 may be formed such that the second I/O pad 405 is located between the slit 411 and the plurality of cell contact plugs 440.

In some implementations, as shown in a portion D1, the slit 411 may be formed to pass through the third substrate 410. The slit 411 may be used, for example, to prevent fine cracks of the third substrate 410 when the opening portion 408 is formed. However, this is illustrative, and the slit 411 may be formed at a depth of about 60% to about 70% of the thickness of the third substrate 410.

Alternatively, in some implementations, as shown in a portion D2, a conductive material 412 may be formed inside the slit 411. The conductive material 412 may be used, for example, to discharge, to the outside, a leakage current generated while driving circuit devices in the outer pad bonding area PA. In this case, the conductive material 412 may be connected to an external ground line.

Alternatively, in some implementations, as shown in a portion D3, an insulating material 413 may be formed inside the slit 411. The insulating material 413 may be formed, for example, to electrically isolate the second I/O pad 405 and the second I/O contact plug 403 disposed in the outer pad bonding area PA from the word line bonding area WLBA. By forming the insulating material 413 inside the slit 411, it may be blocked that a voltage provided through the second I/O pad 405 affects a metal layer disposed on the third substrate 410 in the word line bonding area WLBA.

According to some implementations, the first to third I/O pads 205, 405, and 406 may be selectively formed. For example, the memory device 500 may be implemented to include only the first I/O pad 205 disposed on the first substrate 201, only the second I/O pad 405 disposed on the third substrate 410, or only the third I/O pad 406 disposed on the upper insulating layer 401.

According to some implementations, at least one of the second substrate 310 of the first cell area CELL1 and the third substrate 410 of the second cell area CELL2 may be used as a sacrificial substrate, and the sacrificial substrate may be entirely or only partially removed before or after a bonding process. An additional layer may be stacked after the substrate removal. For example, the second substrate 310 of the first cell area CELL1 may be removed before or after the peripheral circuit area PERI is bonded to the first cell area CELL1, and an insulating layer covering the upper surface of the common source line 320 or a conductive layer for connection may be formed. Likewise, the third substrate 410 of the second cell area CELL2 may be removed before or after the first cell area CELL1 is bonded to the second cell area CELL2, and the upper insulating layer 401 covering the upper surface of the common source line 420 or a conductive layer for connection may be formed.

According to the present implementations, the upper bonding metals 270c of the peripheral circuit area PERI may be disposed at an upper portion of a page buffer circuit area in a matrix form in the first direction (the Y-axis direction) and the second direction (the X-axis direction). The page buffer circuit area may correspond to the bit line bonding area BLBA. For example, the upper bonding metals 270c may be grouped to a plurality of bonding pad groups, and each bonding pad group may include upper bonding metals 270c arranged in a row in the first direction (the Y-axis direction). According to the present implementations, the peripheral circuit area PERI may include a plurality of through wirings extending in the first direction (the Y-axis direction). For example, each through wiring may be disposed between adjacent bonding pad groups.

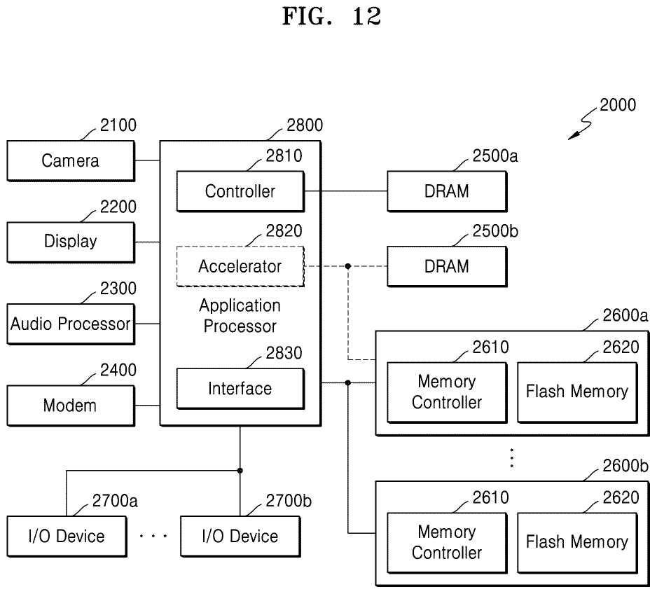

FIG. 12 is a block diagram of a system 2000 for describing an electronic device including a receiver circuit according to implementations.

Referring to FIG. 12, the system 2000 may include a camera 2100, a display 2200, an audio processor 2300, a modem 2400, DRAMs 2500a and 2500b, flash memories 2600a and 2600b, I/O devices 2700a and 2700b, and an application processor (AP) 2800. The system 2000 may be implemented by a laptop computer, a mobile phone, a smartphone, a tablet PC, a wearable device, a healthcare device, or Internet of Things (IoT) device. Alternatively, the system 2000 may be implemented by a server or a PC.

The camera 2100 may capture a still image or a moving picture according to control by a user and store the captured image/video data or transmit the same to the display 2200. The audio processor 2300 may process audio data included in content in the flash memories 2600a and 2600b or from a network. The modem 2400 may modulate and transmit a signal for wired/wireless data transmission and reception and demodulate a signal into an original signal at a reception side. The I/O devices 2700a and 2700b may include devices, such as a universal serial bus (USB) or a storage, a digital camera, a secure digital (SD) card, a digital versatile disc (DVD), a network adapter, and a touch screen, for providing a digital input and/or output function.

The AP 2800 may control a general operation of the system 2000. The AP 2800 may include a controller block 2810, an accelerator block or accelerator chip 2820, and an interface block 2830. The AP 2800 may control the display 2200 to display, on the display 2200, a portion of content stored in the flash memories 2600a and 2600b. If a user input is received through the I/O devices 2700a and 2700b, the AP 2800 may perform a control operation corresponding to the user input. The AP 2800 may include the accelerator block that is an exclusive circuit for artificial intelligence (AI) data computation, or the accelerator chip 2820 may be provided separately from the AP 2800. The DRAM 2500b may be additionally mounted in the accelerator block or accelerator chip 2820. An accelerator is a function block configured to professionally perform a particular function of the AP 2800 and may include a graphics processing unit (GPU) that is a function block configured to professionally perform graphics data processing, a neural processing unit (NPU) that is a block configured to professionally perform AI computation and inference, and a data processing unit (DPU) that is a block configured to professionally perform data transmission. In some implementations, an image captured by a user through the camera 2100 may be signal-processed and stored in the DRAM 2500b, and the accelerator block or accelerator chip 2820 may perform AI data computation for recognizing data by using data stored in the DRAM 2500b and a function used for inference.

The system 2000 may include a plurality of DRAMs 2500a and 2500b. The AP 2800 may control the DRAMs 2500a and 2500b through a command and a mode register set (MRS) according to the Joint Electron Device Engineering Council (JEDEC) standard or communicate with the DRAMs 2500a and 2500b by setting a DRAM interface protocol to use company-specific functions, such as low voltage/high speed/reliability, and a cyclic redundancy check (CRC)/error correction code (ECC) function. For example, the AP 2800 may communicate with the DRAM 2500a by using an interface, which meets the JEDEC standard, such as low power double data rate 4 (LPDDR4) or LPDDR5, and the accelerator block or accelerator chip 2820 may communicate with the DRAM 2500b by setting a new DRAM interface protocol to control the DRAM 2500b having a higher bandwidth than the DRAM 2500a, the DRAM 2500b being for an accelerator.

Although FIG. 12 shows only the DRAMs 2500a and 2500b, this disclosure is not limited thereto, and only if satisfying the bandwidth, responding speed, and voltage conditions of the AP 2800 or the accelerator chip 2820, any memory, such as phase-change random access memory (PRAM), static random access memory (SRAM), magnetoresistive random access memory (MRAM), resistive random access memory (RRAM), ferroelectric random access memory (FRAM), or hybrid RAM, may be used. The DRAMs 2500a and 2500b have a relatively lower latency and narrower bandwidth than those of the I/O devices 2700a and 2700b or the flash memories 2600a and 2600b. The DRAMs 2500a and 2500b may be initialized at a power-on time point of the system 2000 and used as a temporary storage of an operating system (OS) and application data by loading the OS and the application data thereon or used as an execution space of various kinds of software code.

In the DRAMs 2500a and 2500b, the four fundamental arithmetic operations, such as addition/subtraction/multiplication/division, a vector operation, an address operation, or a fast Fourier transform (FFT) operation may be performed. In addition, in the DRAMs 2500a and 2500b, a function used for inference may be performed. Herein, the inference may be performed in a deep learning algorithm using an artificial neural network. The deep learning algorithm may include a training operation of training a model through various pieces of data and an inference operation of recognizing data by using the trained model.

The system 2000 may include a plurality of storages or a plurality of flash memories 2600a and 2600b having a higher capacity than that of the DRAMs 2500a and 2500b. The accelerator block or accelerator chip 2820 may perform the training operation and an AI data computation by using the flash memories 2600a and 2600b. In some implementations, each of the flash memories 2600a and 2600b may include a memory controller 2610 and a flash memory device 2620, and the training operation and the AI data computation performed by the AP 2800 and/or the accelerator chip 2820 may be further efficiently performed using a computation device included in the memory controller 2610. The flash memories 2600a and 2600b may store pictures taken through the camera 2100 or store data received through a data network. For example, the flash memories 2600a and 2600b may store augmented reality/virtual reality, high definition (HD), or ultra high definition (UHD) content.

The components of the system 2000 may include the receiver circuits described with reference to FIGS. 1 to 10. A receiver circuit may include a differential transistor pair configured to receive an input signal, a pair of output nodes configured to output a response to the input signal, the pair of output nodes including a first output node configured to output a first output signal and a second output node configured to output a second output signal, a third transistor connected between the first output node and the second output node, and a capacitive element connected between an input signal line through which the input signal is received and the third transistor. A response gain for the input signal may be superposed on the second output signal by compensating for the gain and bandwidth of a second output signal path having a low gain and a narrow bandwidth through the third transistor and the capacitive element which implement an asymmetric bandwidth compensation circuit. The receiver circuit may compensate for only the bandwidth of a path having a low gain, thereby improving the performance of the receiver circuit and reducing power consumption. The receiver circuit may be usefully applied to semiconductor integrated circuits, such as a memory device and a system on chip.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the present disclosure has been particularly shown and described with reference to implementations thereof, it will be understood that various changes in form and details may be made therein without departing from the spirit and scope of the following claims.

What is claimed is:

1. A receiver circuit comprising:
a first transistor configured to receive an input signal;
a second transistor configured to receive a reference voltage;
a first output node connected to a first end of the first transistor and configured to output a first output signal;
a second output node connected to a first end of the second transistor;
a third transistor connected between the first output node and the second output node, a control end of the third transistor configured to receive the first output signal and a first end of the third transistor configured to output a second output signal;
an input signal line arranged to provide the input signal; and
a capacitive element connected between the input signal line and a second end of the third transistor,
wherein the third transistor and the capacitive element are configured to superpose a response gain on the input signal to provide the second output signal.

2. The receiver circuit of claim 1, comprising:
a first resistor connected between the first output node and a ground voltage line of the receiver circuit; and
a second resistor connected between the second output node and the ground voltage line,
wherein the response gain is a function of the first resistor and the second resistor.

3. The receiver circuit of claim 2, comprising:
a first current source connected between a power source voltage line of the receiver circuit and second ends of the first transistor and the second transistor;
a second current source connected between the power source voltage line and the second end of the third transistor;
a third current source connected between the power source voltage line and a first end of a fourth transistor; and
the fourth transistor connected between the third current source and the first output node,
wherein a second end of the fourth transistor is connected to the first output node, and a control end of the fourth transistor is connected to the ground voltage line.

4. The receiver circuit of claim 3, comprising:
a fourth current source connected between the second output node and the ground voltage line; and
a fifth current source connected between the first output node and the ground voltage line.

5. The receiver circuit of claim 2, comprising:
a first current source connected between a power source voltage line of the receiver circuit and second ends of the first transistor and the second transistor;
a second current source connected between the power source voltage line and the second end of the third transistor; and
a third current source connected between the power source voltage line and the first output node.

6. The receiver circuit of claim 1, comprising:
a first resistor connected between the first output node and a power source voltage line of the receiver circuit; and
a second resistor connected between the second output node and the power source voltage line,
wherein the response gain is a function of the first resistor and the second resistor.

7. The receiver circuit of claim 6, comprising:
a first current source connected between a ground voltage line of the receiver circuit and second ends of the first transistor and the second transistor;
a second current source connected between the ground voltage line and the second end of the third transistor;
a third current source connected between the ground voltage line and a first end of a fourth transistor; and
the fourth transistor connected between the third current source and the first output node,
wherein a second end of the fourth transistor is connected to the first output node, and a control end of the fourth transistor is connected to the power source voltage line.

8. The receiver circuit of claim 7, comprising:
a fourth current source connected between the power source voltage line and the second output node; and
a fifth current source connected between the power source voltage line and the first output node.

9. The receiver circuit of claim 6, comprising:
a first current source connected between second ends of the first transistor and the second transistor and a ground voltage line of the receiver circuit;
a second current source connected between the second end of the third transistor and the ground voltage line; and
a third current source connected between the first output node and the ground voltage line.

10. A method for a receiver circuit, the method comprising:
receiving an input signal by a first transistor through an input signal line and a reference voltage by a second transistor, wherein a first end of a capacitive element is connected to the input signal line, and wherein a first end of a third transistor is connected to a second end of the capacitive element;
providing currents through a pair of output nodes, wherein the pair of output nodes comprises a first output node and a second output node and wherein the third transistor is connected to a first output node of the pair of output nodes; and
outputting a response to the input signal from the pair of output nodes, wherein outputting the response comprises outputting a first output signal from the first output node and outputting a second output signal from the second output node, wherein a second end of the third transistor is connected to the second output node,
wherein the third transistor and the capacitive element superpose a response gain on the input signal to provide the second output signal.

11. The method of claim 10, wherein the response gain is a function of resistors connected to the pair of output nodes.

12. The method of claim 11, wherein providing currents through the pair of output nodes comprises providing the currents through the first transistor, the second transistor, the third transistor, and the first output node by using at least one current source connected to a power source voltage line of the receiver circuit.

13. The method of claim 11, wherein outputting the response to the input signal from the pair of output nodes comprises using a fourth transistor, wherein a first end of the fourth transistor is connected to the first output node, and wherein a control end of the fourth transistor is connected to a ground voltage line of the receiver circuit.

14. The method of claim 13, wherein providing the currents through the pair of output nodes comprises providing the currents through the first transistor, the second transistor, the third transistor, and the fourth transistor by using at least a first current source connected to a power source voltage line of the receiver circuit.

15. The method of claim 14, wherein providing the currents through the third transistor and the fourth transistor comprises using at least a second current source connected to the ground voltage line.

16. The method of claim 11, wherein providing the currents through the pair of output nodes comprises providing the currents through the first transistor, the second transistor, the third transistor, and the first output node by using at least one current source connected to a ground voltage line of the receiver circuit.

17. The method of claim 11, wherein outputting the response to the input signal from the pair of output nodes comprises using a fourth transistor, wherein a first end of the fourth transistor is connected to the first output node, and wherein a control end of the fourth transistor is connected to a power source voltage line of the receiver circuit.

18. The method of claim 17, wherein providing the currents through the pair of output nodes comprises providing the currents through the first transistor, the second transistor, the third transistor, and the fourth transistor by using at least a first current source connected to a ground voltage line of the receiver circuit.

19. The method of claim 18, comprising providing the currents through the third transistor and the fourth transistor by using at least a second current source connected to the power source voltage line of the receiver circuit.

20. A receiver circuit comprising:
a first transistor configured to receive an input signal;
a second transistor configured to receive a complementary input signal;
a first output node connected to a first end of the first transistor and configured to output a first output signal;
a second output node connected to a first end of the second transistor;
a third transistor connected between the first output node and the second output node,
wherein a control end of the third transistor is configured to receive the first output signal and a first end of the third transistor is configured to output a second output signal; and
a capacitive element connected between an input signal line through which the input signal is received and a second end of the third transistor,
wherein the third transistor and the capacitive element are configured to superpose a response gain on the input signal to provide the second output signal.
